(19) United States
(12) Patent Application Publication
(10) Pub. No.: US 2026/0189242 A1
(43) Pub. Date: Jul. 2, 2026

(54) ANALOG-TO-DIGITAL CONVERTER, ELECTRONIC DEVICE, AND METHOD FOR CONTROLLING ANALOG-TO-DIGITAL CONVERTER

(71) Applicant: SONY SEMICONDUCTOR SOLUTIONS CORPORATION, Kanagawa (JP)

(72) Inventors: Hiroshi YOSHIDA, Kanagawa (JP); Shinichi TANABE, Kanagawa (JP)

(73) Assignee: SONY SEMICONDUCTOR SOLUTIONS CORPORATION, Kanagawa (JP)

(21) Appl. No.: 18/862,302

(22) PCT Filed: Mar. 16, 2023
(86) PCT No.: PCT/JP2023/010334

§ 371 Date: Nov. 1, 2024

(30) Foreign Application Priority Data
May 11, 2022 (JP) 2022-078112

(51) Int. Cl. H03M 1/10

(52) U.S. Cl. CPC H03M 1/1042; H03M 1/1071

(57) ABSTRACT

A circuit scale of a circuit that performs correction is reduced. An analog-to-digital converter includes an analog-to-digital conversion circuit, a correction value table, and a correction unit. In this analog-to-digital converter, the analog-to-digital conversion circuit converts an analog signal into a digital signal. Furthermore, in the correction value table, a correction value for correcting a non-linearity error of the analog-to-digital conversion circuit is held in association with a value of the digital signal. The correction unit corrects the digital signal using the correction value.

### TECHNICAL FIELD

The present technology relates to an analog-to-digital converter. More specifically, the present technology relates to an analog-to-digital converter that corrects an error, an electronic device, and a method for controlling the analog-to-digital converter.

### BACKGROUND ART

Analog-to-digital converters (ADCs) have been conventionally used to convert analog signals into digital signals in various electronic devices such as a reception device and an imaging device. A locus representing a relationship between an input signal (that is, an analog signal) and an output signal (that is, a digital signal) of such an ADC might deviate from a straight line due to various factors. Such an error due to deviation is called an integral non-linearity (INL) error. For example, an ADC has been proposed in which a distortion component is modeled through training and represented by a nonlinear function in order to correct an INL error (see, for example, Patent Document 1).

### CITATION LIST

### Patent Document

Patent Document 1: Japanese Translation of PCT International Application Publication No. 2007-521743

### SUMMARY OF THE INVENTION

### Problems to be Solved by the Invention

In the above-described conventional technique, the INL error is reduced by using a nonlinear function representing a distortion component. In a case where a nonlinear function is used, however, a large number of adders and multipliers are required, and there is a problem that a circuit scale of a circuit that performs correction in an ADC increases.

The present technology has been made in view of such circumstances, and an object thereof is to reduce a circuit scale of a circuit that performs correction in an analog-to-digital converter that corrects a non-linearity error.

### Solutions to Problems

The present technology has been made to solve the above-described problem, and a first aspect thereof is an analog-to-digital converter including an analog-to-digital conversion circuit that converts an analog signal into a digital signal, a correction value table that holds a correction value for correcting a non-linearity error of the analog-to-digital conversion circuit in association with a value of the digital signal, and a correction unit that corrects the digital signal using the correction value, and a method for controlling the analog-to-digital converter. This leads to an effect of simplifying configuration of the correction unit.

Furthermore, in the first aspect, a reference voltage generation unit that generates a predetermined reference voltage, a selection unit that selects the reference voltage or an input analog signal and that supplies the selected reference voltage or input analog signal to the analog-to-digital conversion circuit, and a measurement unit that obtains the correction value from a measured value of the digital signal corresponding to the reference voltage and a predetermined ideal value may be further included. This leads to an effect of generating a correction value in the analog-to-digital converter.

Furthermore, an output range of the reference voltage generation unit may substantially match with an input range of the analog-to-digital conversion circuit. This leads to an effect of improving accuracy of correction.

Furthermore, in the first aspect, the measurement unit may obtain a difference between the measured value and the ideal value as the correction value, and the correction value table may hold the correction value for each value of the digital signal. This leads to an effect of accurately correcting an error.

Furthermore, in the first aspect, values of the digital signal may be divided into a predetermined number of ranges, the measurement unit may obtain, for each range, a representative value of differences between measured values and the ideal value within the range as the correction value, and the correction value table may hold the correction value for each range. This leads to an effect of reducing size of the correction value table.

Furthermore, in the first aspect, a multiplier that performs sign extension on the digital signal through multiplication and that supplies the digital signal to the correction unit may be further included, and the measurement unit may calculate a value obtained by dividing an integrated value of differences between measured values and the ideal value by a predetermined divisor as the correction value. This leads to an effect of improving resolution of the analog-to-digital converter.

Furthermore, in the first aspect, resolution of the analog-to-digital conversion circuit may be n bits, where n is an integer, the multiplier may multiply the digital signal by 2^{m}, where m is an integer, the number of integrations of the differences may be 2^{(k+m)}, where k is an integer, and the divisor may be 2^{k}. This leads to an effect of extending bit width of the digital signal by m bits.

Furthermore, a second aspect of the present technology is an electronic device including an analog-to-digital conversion circuit that converts an analog signal into a digital signal, a correction value table that holds a correction value for correcting a non-linearity error of the analog-to-digital conversion circuit in association with a value of the digital signal, a correction unit that corrects the digital signal using the correction value, and a signal processing unit that performs predetermined processing on the corrected digital signal. This leads to an effect of simplifying the configuration of the correction unit in the electronic device.

### BRIEF DESCRIPTION OF DRAWINGS

FIG. 1 is a block diagram illustrating a configuration example of a reception device according to a first embodiment of the present technology.

FIG. 2 is a block diagram illustrating a configuration example of an analog-to-digital converter according to the first embodiment of the present technology.

FIG. 3 is a block diagram and a circuit diagram illustrating a configuration example of a reference voltage generation unit according to the first embodiment of the present technology.

FIG. 4 is a diagram for describing a method of adjusting an output range of a reference voltage generation unit according to the first embodiment of the present technology.

FIG. 5 is a block diagram illustrating a configuration example of a measurement unit according to the first embodiment of the present technology.

FIG. 6 is a flowchart illustrating an example of operation of the analog-to-digital converter according to the first embodiment of the present technology.

FIG. 7 is a flowchart illustrating an example of a process for generating a correction value table according to the first embodiment of the present technology.

FIG. 8 is a diagram illustrating correction examples and correction values corresponding to indices of 0 to 15 according to the first embodiment of the present technology.

FIG. 9 is a diagram illustrating correction examples and correction values corresponding to indices of 16 to 31 according to the first embodiment of the present technology.

FIG. 10 is a diagram illustrating correction examples and correction values corresponding to indices of 32 to 47 according to the first embodiment of the present technology.

FIG. 11 is a diagram illustrating correction examples and correction values corresponding to indices of 48 to 63 according to the first embodiment of the present technology.

FIG. 12 is a diagram illustrating an example of a relationship between an INL component and a signal-to-noise and distortion ratio (SINAD) according to the first embodiment of the present technology.

FIG. 13 is a diagram illustrating an example of frequency characteristics before correction in a case where a sine wave signal is input according to the first embodiment of the present technology.

FIG. 14 is a diagram illustrating an example of frequency characteristics after the correction in a case where a sine wave signal is input according to the first embodiment of the present technology.

FIG. 15 is a diagram illustrating an example of an INL component and a correction value corresponding to an input signal according to the first embodiment of the present technology.

FIG. 16 is a diagram for describing an effect of correction according to the first embodiment of the present technology.

FIG. 17 is a diagram illustrating an example of an AD conversion error corresponding to an input signal according to the first embodiment of the present technology.

FIG. 18 is a block diagram illustrating a configuration example of an analog-to-digital converter according to a second embodiment of the present technology.

FIG. 19 is a block diagram illustrating a configuration example of a measurement unit according to the second embodiment of the present technology.

FIG. 20 is a flowchart illustrating an example of operation of the analog-to-digital converter according to the second embodiment of the present technology.

FIG. 21 is a flowchart illustrating an example of a process for generating a correction value table according to the second embodiment of the present technology.

FIG. 22 is a diagram illustrating correction examples and correction values corresponding to indices of 0 to 60 according to the second embodiment of the present technology.

FIG. 23 is a diagram illustrating correction examples and correction values corresponding to indices of 64 to 124 according to the second embodiment of the present technology.

FIG. 24 is a diagram illustrating correction examples and correction values corresponding to indices of 128 to 188 according to the second embodiment of the present technology.

FIG. 25 is a diagram illustrating correction examples and correction values corresponding to indices of 192 to 252 according to the second embodiment of the present technology.

FIG. 26 is a diagram for describing an effect of correction according to the second embodiment of the present technology.

FIG. 27 is a diagram illustrating an example of an AD conversion error corresponding to an input signal according to the second embodiment of the present technology.

FIG. 28 is a block diagram illustrating a configuration example of a measurement unit according to a third embodiment of the present technology.

FIG. 29 is a flowchart illustrating an example of a process for generating a correction value table according to the third embodiment of the present technology.

FIG. 30 is a diagram illustrating correction values corresponding to digital signals of 0 to 15 according to the third embodiment of the present technology.

FIG. 31 is a diagram illustrating correction values corresponding to digital signals of 16 to 31 according to the third embodiment of the present technology.

FIG. 32 is a diagram illustrating correction values corresponding to digital signals of 32 to 47 according to the third embodiment of the present technology.

FIG. 33 is a diagram illustrating correction values corresponding to digital signals of 48 to 63 according to the third embodiment of the present technology.

FIG. 34 is a diagram illustrating correction examples corresponding to indices of 0 to 15 according to the third embodiment of the present technology.

FIG. 35 is a diagram illustrating correction examples corresponding to indices of 16 to 31 according to the third embodiment of the present technology.

FIG. 36 is a diagram illustrating correction examples corresponding to indices of 32 to 47 according to the third embodiment of the present technology.

FIG. 37 is a diagram illustrating correction examples corresponding to indices of 48 to 63 according to the third embodiment of the present technology.

FIG. 38 is a diagram for describing an effect of correction according to the third embodiment of the present technology.

FIG. 39 is a diagram illustrating an example of an INL component before and after the correction according to the third embodiment of the present technology.

FIG. 40 is a diagram illustrating an example of an AD conversion error corresponding to an input signal according to the third embodiment of the present technology.

### MODE FOR CARRYING OUT THE INVENTION

Modes for carrying out the present technology (hereinafter referred to as embodiments) will be described hereinafter. The description will be given in the following order.
1. First Embodiment (Example of Correction Using Correction Value in Correction Value Table)
2. Second Embodiment (Example of Code Extension and Correction Using Correction Value in Correction Value Table)
3. Third Embodiment (Example in which Representative Value Is Held as Correction Value in Correction Value Table and Correction Is Performed Using Correction Value)

### 1. First Embodiment

### Configuration Example of Electronic Device

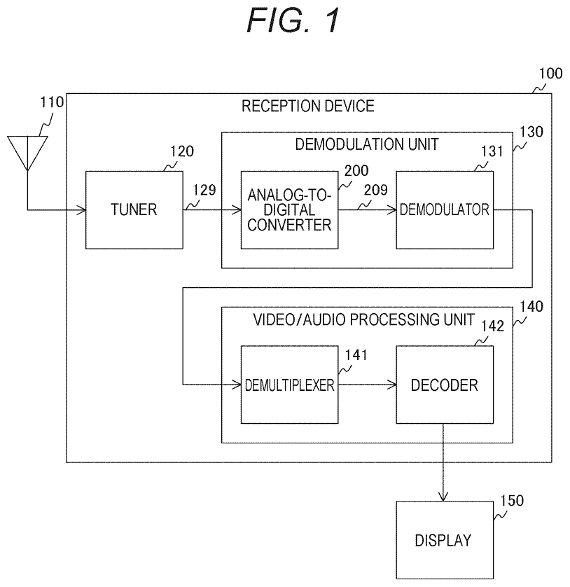

FIG. 1 is a block diagram illustrating a configuration example of a reception device 100 according to a first embodiment of the present technology. The reception device 100 is a device for receiving wireless signals such as terrestrial digital broadcast signals, and includes an antenna 110, a tuner 120, a demodulation unit 130, and a video/audio processing unit 140. Furthermore, the demodulation unit 130 includes an analog-to-digital converter 200 and a demodulator 131. The video/audio processing unit 140 includes a demultiplexer 141 and a decoder 142.

The antenna 110 converts an electromagnetic wave from a broadcasting station into a radio frequency (RF) signal. The tuner 120 converts the RF signal from the antenna 110 into an analog intermediate frequency (IF) signal. The tuner 120 supplies the IF signal, as an input signal, to the analog-to-digital converter 200 via a signal line 129.

The analog-to-digital converter 200 converts the input signal (that is, the analog signal) into a digital signal. The analog-to-digital converter 200 supplies the digital signal to the demodulator 131 via a signal line 209.

The demodulator 131 performs demodulation on the digital signal and supplies the digital signal to the demultiplexer 141. The demultiplexer 141 demultiplexes multiplexed video signal and audio signal from the demodulated signal. The decoder 142 decodes the video signal and the like and supplies the video signal and the like to a display 150.

Note that although the analog-to-digital converter 200 is provided in the reception device 100, the analog-to-digital converter 200 may be provided in various electronic devices other than the reception device 100, such as a sound device and an imaging device. Note that the reception device 100 is an example of an electronic device described in the claims. Furthermore, the demodulation unit 130 and the video/audio processing unit 140 are examples of a signal processing unit described in the claims.

### Configuration Example of Analog-to-Digital Converter

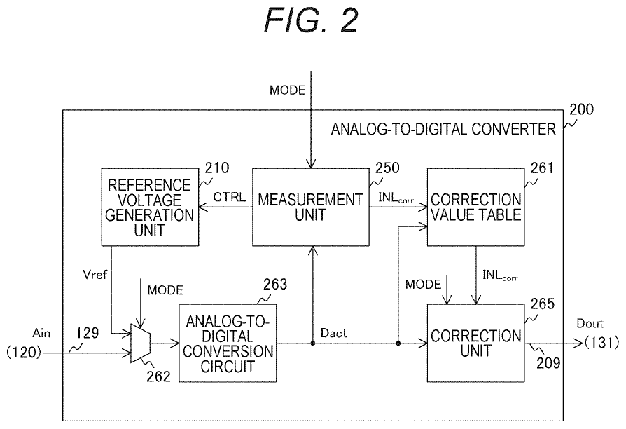

FIG. 2 is a block diagram illustrating a configuration example of the analog-to-digital converter 200 in the first embodiment of the present technology. The analog-to-digital converter 200 includes a reference voltage generation unit 210, a measurement unit 250, a correction value table 261, a multiplexer 262, an analog-to-digital conversion circuit 263, and a correction unit 265.

The reference voltage generation unit 210 generates reference voltages Vref in accordance with a control signal CTRL from the measurement unit 250 and supplies the reference voltages Vref to the multiplexer 262. A digital-to-analog converter (DAC), for example, is used as the reference voltage generation unit 210. Furthermore, the reference voltage generation unit 210 generates multi-stage voltages covering an entire input range of the analog-to-digital conversion circuit 263 as the reference voltages Vref. For example, in a case where resolution of the analog-to-digital conversion circuit 263 is n (n is an integer) bits, 2ⁿ-stage voltages obtained by dividing the input range by 2ⁿ are sequentially generated as the reference voltages Vref.

The correction value table 261 holds correction values INL_{corr} for correcting an integral non-linearity (INL) error of the analog-to-digital conversion circuit 263. Assuming that the resolution of the analog-to-digital conversion circuit 263 is n bits, an n-bit code is generated as a digital signal Dact, and values of the code are, for example, 0 to 2ⁿ−1. For each of these values, a correction value INL_{corr} for correcting the value is held.

The multiplexer 262 selects an analog input signal Ain from the tuner 120 or the reference voltage Vref in accordance with a mode signal MODE, and supplies the analog input signal Ain or the reference voltage Vref to the analog-to-digital conversion circuit 263. Note that the multiplexer 262 is an example of a selection unit described in the claims.

Here, the mode signal MODE is a signal indicating a calibration mode or a normal mode, and is input from, for example, the outside of the analog-to-digital converter 200. The calibration mode is a mode in which the analog-to-digital converter 200 measures an INL error thereof and generates a correction value INL_{corr}. The normal mode, on the other hand, is a mode in which the analog-to-digital converter 200 converts the input signal Ain (analog signal) into a digital signal Dout.

Switching to the calibration mode is performed in a case where the reception device 100 is activated or a predetermined event occurs. In a case where the generation of the correction value INL_{corr} is completed, the calibration mode is switched to the normal mode.

The multiplexer 262 selects the reference voltage Vref in the calibration mode and selects the input signal Ain in the normal mode.

The analog-to-digital conversion circuit 263 converts the analog signal from the multiplexer 262 into a digital signal Dact and supplies the digital signal Dact to the measurement unit 250 and the correction unit 265. As the analog-to-digital conversion circuit 263, for example, a single-slope analog-to-digital converter (ADC) or a successive approximation register ADC (SARADC) is used.

Furthermore, the digital signal is also supplied to an access circuit (not illustrated) that accesses the correction value table 261. The access circuit reads a correction value INL_{corr} corresponding to the digital signal from a memory and supplies the correction value INL_{corr} to the correction unit 250.

The correction unit 265 corrects the digital signal Dact. In the normal mode, the correction unit 265 obtains a correction value INL_{corr} corresponding to a value of the digital signal Dact from the correction value table 261. The correction unit 265 then corrects the digital signal Dact with the correction value INL_{corr} and supplies the corrected digital signal to the demodulator 131 as Dout.

The measurement unit 250 measures the digital signal Dact to obtain the correction value INL_{corr}. In a case where the calibration mode is specified by the mode signal MODE, the measurement unit 250 controls the reference voltage generation unit 210 to sequentially generate the 2ₙ-stage reference voltages Vref. The measurement unit 250 then obtains a correction value INL_{corr} from a measured value of the digital signal Dact corresponding to the reference voltage Vref and an ideal value in a case where there is no INL error, and holds the correction value INL_{corr} in the correction value table 261.

### Configuration Example of Reference Voltage Generation Unit

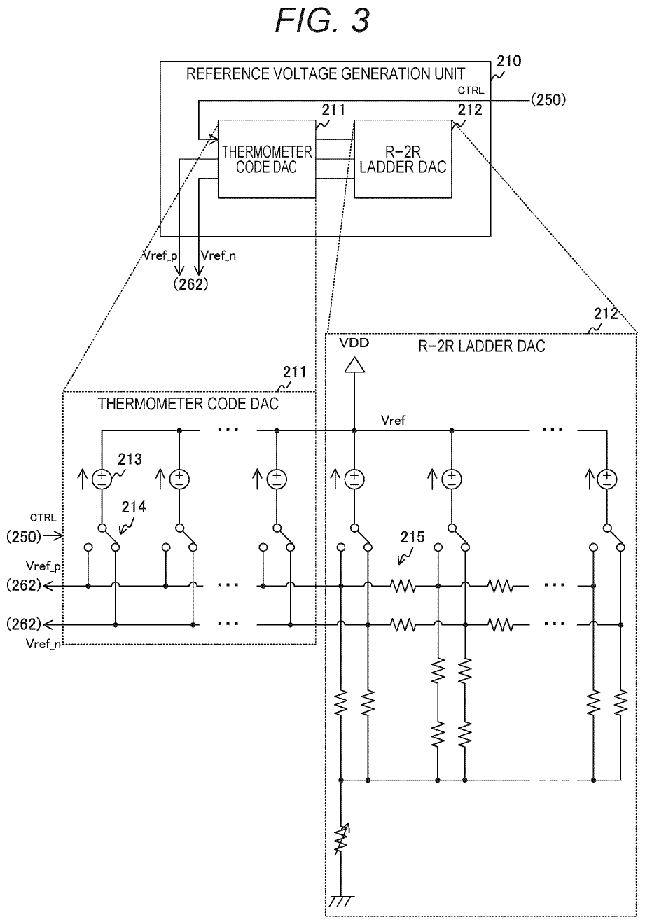

FIG. 3 is a block diagram and a circuit diagram illustrating a configuration example of the reference voltage generation unit 210 according to the first embodiment of the present technology. The reference voltage generation unit 210 includes, for example, a thermometer code DAC 211 and an R-2R ladder DAC 212. For example, upper bits of the control signal CTRL are input to the thermometer code DAC 211, and lower bits are input to the R-2R ladder DAC 212.

Furthermore, a plurality of current sources 213, a plurality of switches 214, and a plurality of resistance elements 215 are arranged in these DACs. The current sources 213 supply a constant current. A current value of the current sources 213 can be changed by a set value of a register or the like.

The switch 214 connects a current source 213 to either a positive output line or a negative output line in accordance with a value of a corresponding bit of the control signal CTRL.

With the circuit configuration illustrated in the drawing, a positive voltage Vref_p and a negative voltage Vref_n are generated. A difference between these corresponds to the reference voltage Vref.

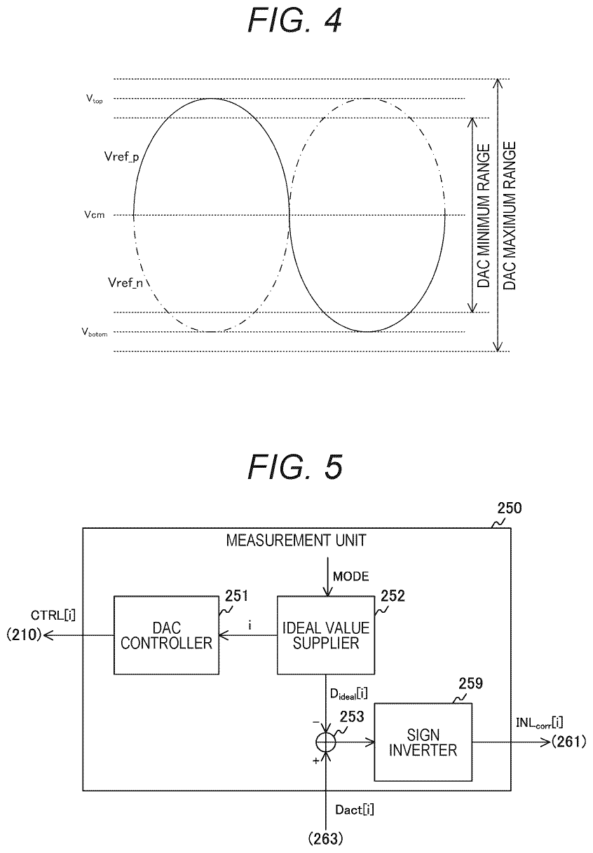

FIG. 4 is a diagram for describing a method of adjusting an output range of the reference voltage generation unit 210 according to the first embodiment of the present technology. If the output range of the reference voltage generation unit 210 does not match the input range of the analog-to-digital conversion circuit 263 in a case where the measurement unit 250 measures a signal including an INL component, the correction unit 265 cannot perform accurate correction.

Here, the output range of the reference voltage generation unit 210 can be adjusted by changing the current value of each of the current sources 213. In order to improve accuracy of correction, it is preferable to substantially match the output range with the input range of the analog-to-digital conversion circuit 263 by adjusting the current value. More specifically, the value of the digital signal Dact in a case where the control signal CTRL to the reference voltage generation unit 210 is set to “0” may be adjusted to be “0”, and the value of the digital signal Dact in a case where the control signal CTRL is set to a full scale may be adjusted to be a full scale.

### Configuration Example of Measurement Unit

FIG. 5 is a block diagram illustrating a configuration example of the measurement unit 250 according to the first embodiment of the present technology. The measurement unit 250 includes a DAC controller 251, an ideal value supplier 252, an adder 253, and a sign inverter 259.

The DAC controller 251 generates a control signal CTRL[i] for generating a reference voltage Vref[i] corresponding to an index i from the ideal value supplier 252, and supplies the control signal CTRL[i] to the reference voltage generation unit 210. Here, the index i is a value assigned to each of the 2ⁿ-stage reference voltages Vref, and set to, for example, 0 to 2ⁿ−1.

The ideal value supplier 252 supplies an ideal value D_{ideal}. The ideal value supplier 252 sequentially generates indices i of 0 to 2ⁿ−1 with a counter or the like and supplies the indices i to the DAC controller 251. Furthermore, the DAC controller 251 sequentially generates an ideal value D_{ideal}[i] in a case where a corresponding reference voltage Vref[i] is converted for each index i, and supplies the ideal value D_{ideal}[i] to the adder 253. For example, the same value (0 to 2ⁿ−1) as the index i is generated as the ideal value D_{ideal}[i].

Note that the index i and the corresponding ideal value D_{ideal}[i] are not limited to the same value.

The adder 253 subtracts the ideal value D_{ideal}[i] from a value (measured value) of a digital signal Dact[i] corresponding to the reference voltage Vref[i], and supplies a difference to the sign inverter 259. The sign inverter 259 inverts a sign of the difference obtained by the adder 253 and holds the difference in the correction value table 261 as a correction value INL_{corr}[i].

The correction value table 261 holds the correction value INL_{corr}[i] in association with the index i. The correction value INL_{corr}[i] is a correction value for correcting the digital signal Dact[i] corresponding to the index i.

In a case where the digital signal Dact[i] is input, the correction unit 265 obtains the corresponding correction value INL_{corr}[i] from the correction value table 261, and performs correction for adding the correction value INL_{corr}[i] to the value of the digital signal Dact[i]. The correction unit 265 then outputs the corrected digital signal as Dout.

Note that the adder 253 may subtract the ideal value D_{ideal}[i] from the digital signal Dact[i] and supply a difference as the correction value INL_{corr}[i]. In this case, the sign inverter 259 is unnecessary, and the correction unit 265 may subtract the correction value INL_{corr}[i] from the digital signal Dact[i].

### Operation Example of Analog-to-Digital Converter

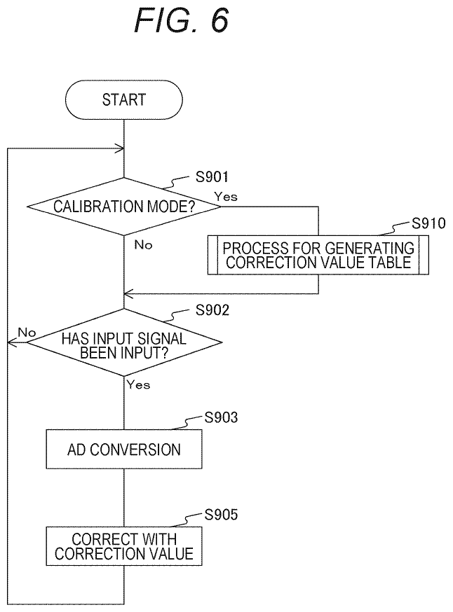

FIG. 6 is a flowchart illustrating an example of operation of the analog-to-digital converter 200 according to the first embodiment of the present technology. This operation is started, for example, in a case where power is supplied.

The analog-to-digital converter 200 determines whether or not a current mode is the calibration mode (step S901). In the calibration mode (step S901: Yes), the analog-to-digital converter 200 starts a process for generating a correction value table (step S910). After the process for generating a correction value table (step S910) ends, the calibration mode is switched to the normal mode, and step S902 and subsequent steps are performed.

In the normal mode (step S901: No), on the other hand, the analog-to-digital converter 200 determines whether or not an analog input signal has been input (step S902). If no input signal has been input (step S902: No), the analog-to-digital converter 200 repeats step S901.

If an input signal is input (step S902: Yes), on the other hand, the analog-to-digital converter 200 performs analog-to-digital (AD) conversion on the input signal to convert the input signal into a digital signal (step S903). The analog-to-digital converter 200 then obtains a corresponding correction value from the correction value table 261, and corrects the digital signal with the correction value (step S905). After step S905, the analog-to-digital converter 200 repeats step S901 and subsequent steps.

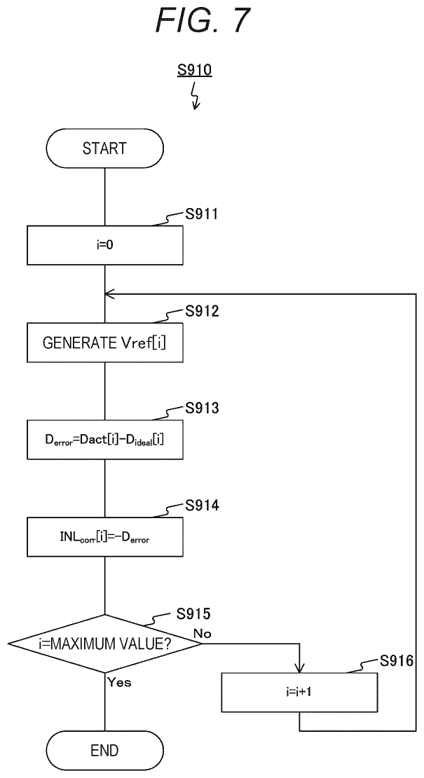

FIG. 7 is a flowchart illustrating an example of the process for generating a correction value table according to the first embodiment of the present technology. The correction unit 265 in the analog-to-digital converter 200 sets the index i to an initial value (for example, “0”) (step S911). The reference voltage generation unit 210 then generates the reference voltage Vref[i] under the control of the measurement unit 250 (step S912).

After the reference voltage Vref[i] is converted into the digital signal Dact[i], the measurement unit 250 calculates an error Dₑᵣᵣₒᵣ using the following expression (step S913).

$${D}_{error} = Dact [ i ] - {D}_{ideal} [ i ] \qquad Expression 1$$

The measurement unit 250 then causes the correction value table 261 to hold a value obtained by inverting a sign of the error Dₑᵣᵣₒᵣ obtained using Expression 1 as a correction value INL_{corr}[i] (step S914).

The measurement unit 250 determines whether or not the index i is a maximum value (2ⁿ−1 or the like) (step S915). If the index i is not the maximum value (step S915: No), the measurement unit 250 increments the index i (step S916), and repeats step S912 and subsequent steps. If the index i is the maximum value (step S915: Yes), on the other hand, the measurement unit 250 ends the process for generating a correction value table.

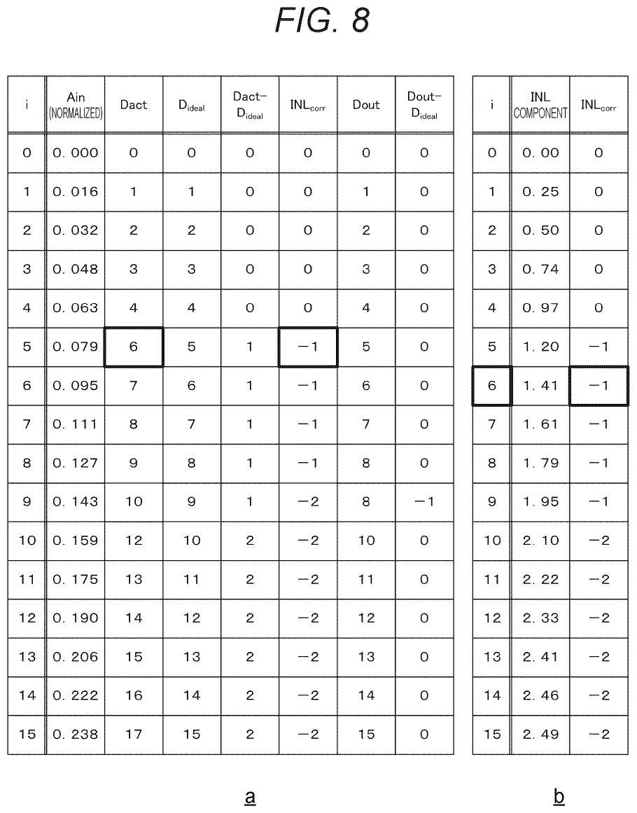

FIG. 8 is a diagram illustrating correction examples and correction values corresponding to indices of 0 to 15 according to the first embodiment of the present technology.

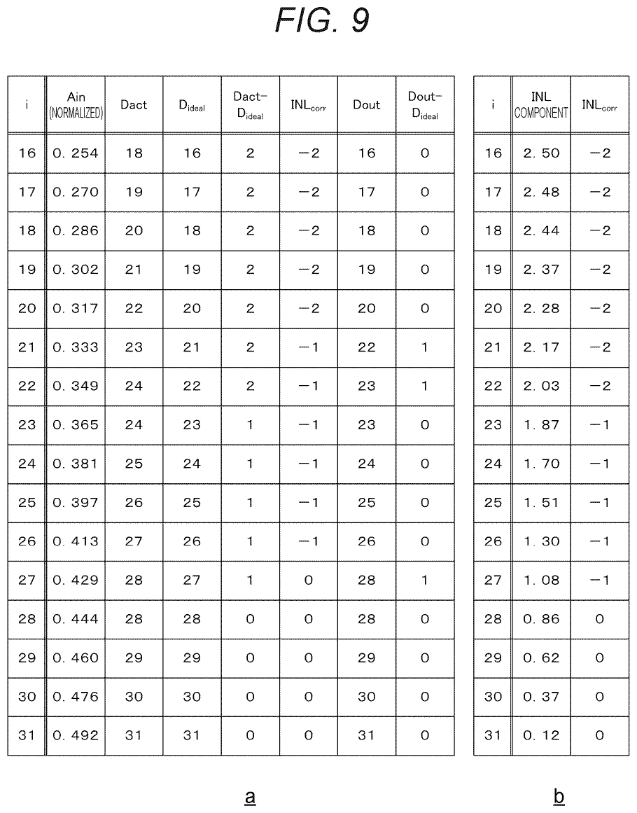

FIG. 9 is a diagram illustrating correction examples and correction values corresponding to indices of 16 to 31 according to the first embodiment of the present technology.

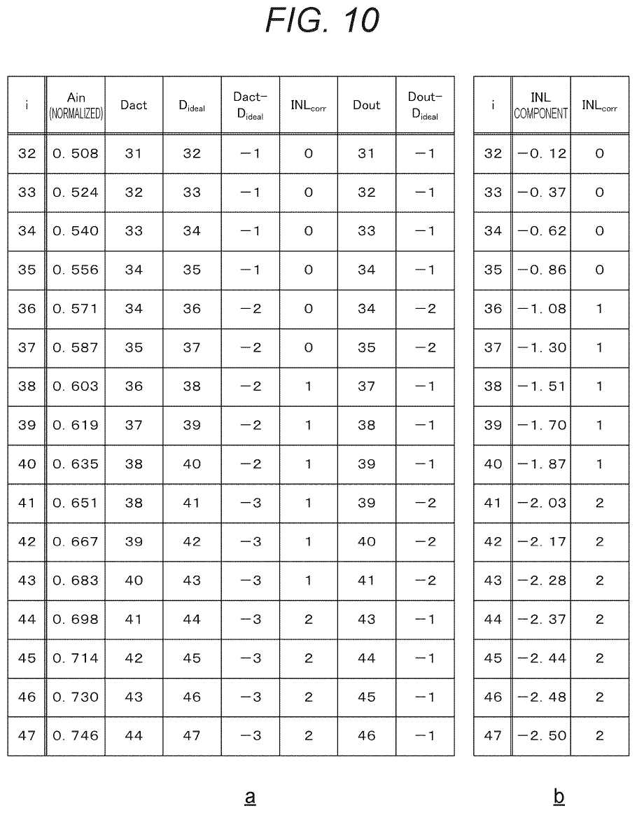

FIG. 10 is a diagram illustrating correction examples and correction values corresponding to indices of 32 to 47 according to the first embodiment of the present technology.

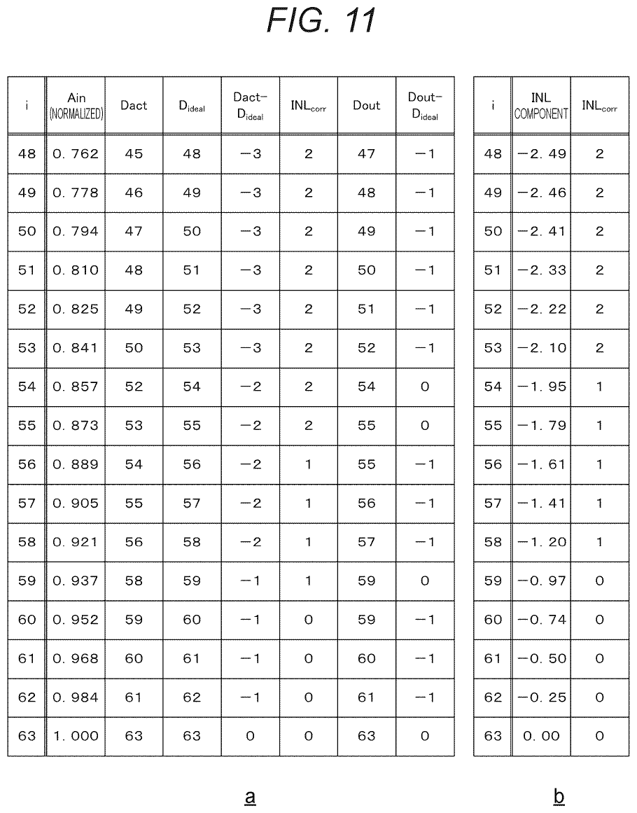

FIG. 11 is a diagram illustrating correction examples and correction values corresponding to indices of 48 to 63 according to the first embodiment of the present technology.

In each of FIGS. 8 to 11, a is a summary of results of the correction, and b in each represents correction values held in the correction value table 261. Furthermore, the resolution of the analog-to-digital converter 200 is assumed to be 6 bits. Note that the resolution is not limited to 6 bits.

As indicated by b of FIG. 8, the correction value table 261 holds the correction values INL_{corr}[i] in association with the index i. The INL component is illustrated in the drawing for reference, but this component is not held in the correction value table 261.

Furthermore, an input signal Ain in a of FIG. 8 indicates a signal normalized to fall within a range of “0.000” to “1.000”.

A case where AD conversion is performed on the input signal Ain corresponding to the index i of “5” is assumed. In this case, it is assumed that the value of the digital signal Dact is “6”. The correction value INL_{corr} corresponding to the index i having the same value as the digital signal Dact is “−1” from the correction value table 261. The correction unit 265 adds the correction value to the digital signal Dact and outputs the obtained “5” as Dout.

Since the ideal value D_{ideal} in a case where the index i is “5” is “5”, an error before the correction (in other words, Dact-D_{ideal}) is “1”. The error after the correction (in other words, Dout-D_{ideal}), on the other hand, is “0”, and the INL error is suppressed through the correction.

As illustrated in FIGS. 8 to 11, by holding a correction value in the correction value table 261 for each value of the digital signal, the correction unit 265 can correct the digital signal through simple calculation.

As described in Patent Document 1, on the other hand, in a case where a nonlinear function is used, it is necessary to provide a large number of adders and multipliers in a circuit that performs correction, and the circuit has a complicated configuration.

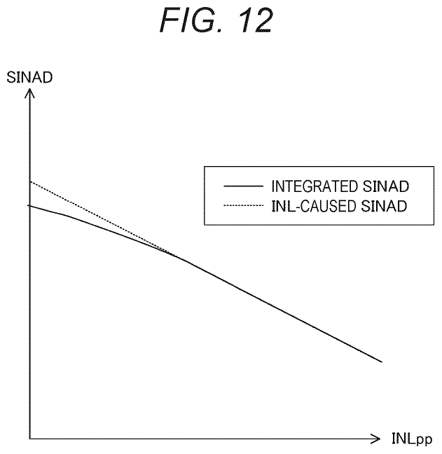

FIG. 12 is a diagram illustrating an example of a relationship between an INL component and a SINAD according to the first embodiment of the present technology. The SINAD is represented by a ratio of signal to noise+distortion, and the distortion increases in proportion to the INL. In the drawing, a vertical axis represents the SINAD, and a horizontal axis represents the INL component. Furthermore, a dotted line indicates a SINAD characteristic with respect to the value of INL, and a solid line indicates a SINAD characteristic with respect to Noise+INL (Distortion).

As illustrated in the drawing, as the INL component increases, the SINAD serving as an index of performance of the analog-to-digital converter 200 deteriorates. The performance of the analog-to-digital converter 200, therefore, can be improved by suppressing the INL component. By performing the correction using the correction value table 261, the INL component can be suppressed as illustrated in the drawing.

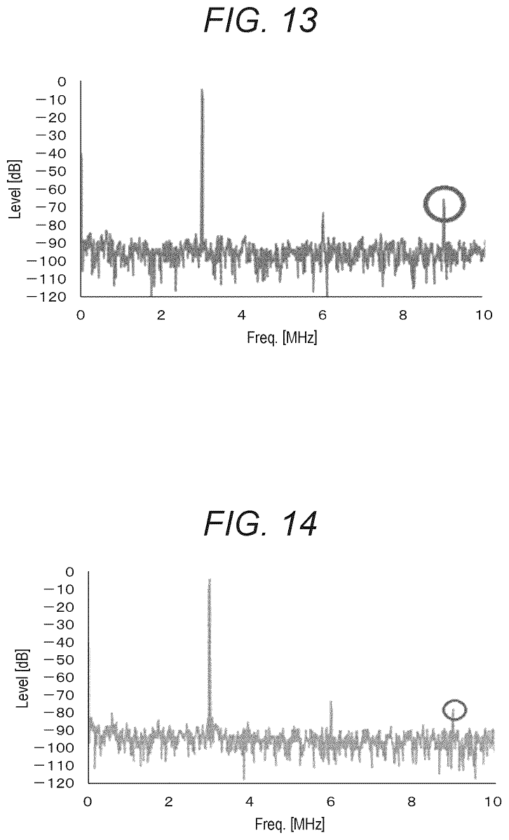

FIG. 13 is a diagram illustrating an example of frequency characteristics before correction in a case where a sine wave signal is input according to the first embodiment of the present technology. In the drawing, a horizontal axis represents a frequency of the input sine wave signal, and a vertical axis represents a level of an output signal before correction. As illustrated in the drawing, third-order harmonic distortion occurs in a portion of in a frequency spectrum surrounded by a circle due to the INL component.

FIG. 14 is a diagram illustrating an example of frequency characteristics after the correction in a case where a sine wave signal is input according to the first embodiment of the present technology. Since the INL component is suppressed through the correction, the third-order harmonic distortion in the circled portion can be reduced, and the SINAD can be improved as illustrated in the drawing.

Although FIGS. 13 and 14 illustrate a case where third-order harmonic distortion is suppressed, a harmonic distortion component depends on a correction value table (such as the correction value table 261) reflecting an INL characteristic, and the SINAD can be improved through correction for any component other than a third-order harmonic distortion component.

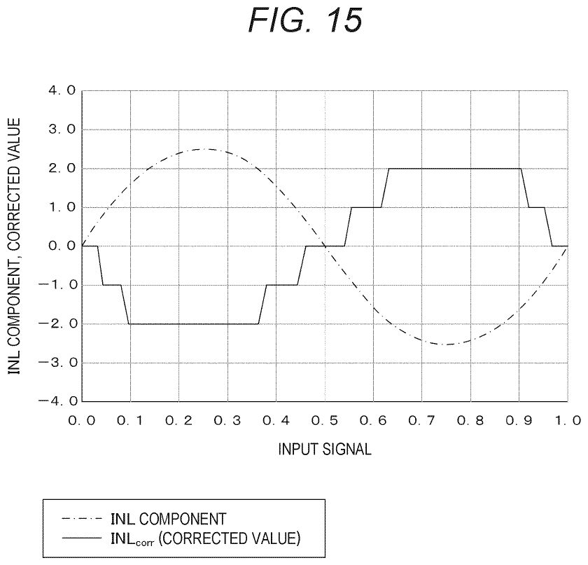

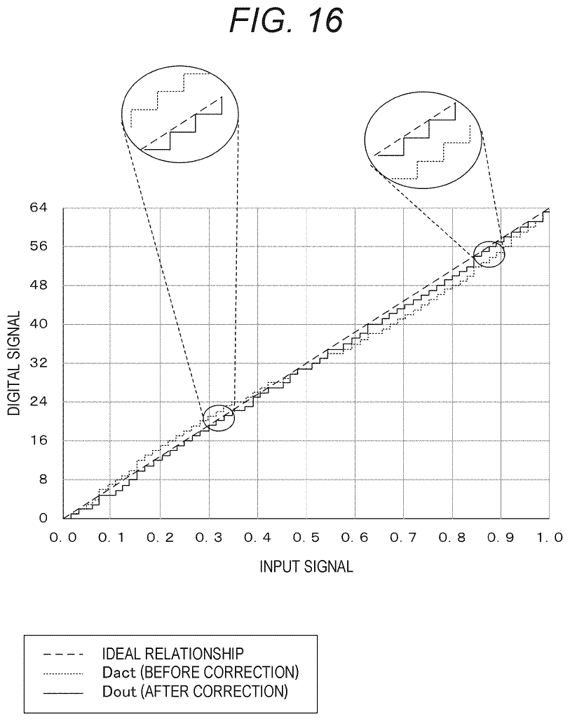

FIG. 15 is a diagram illustrating an example of an INL component and a correction value corresponding to an input signal according to the first embodiment of the present technology. In the drawing, a vertical axis represents the INL component or the correction value, and a horizontal axis represents an input signal normalized to fall within a range from “0.0” to “1.0”. Furthermore, a dash-dot line indicates the INL component, and a solid line indicates the correction value. As illustrated in the drawing, a correction value having a polarity opposite to that of the INL component is generated. Furthermore, as the INL component becomes larger, a correction value having a larger absolute value is used. This correction value reduces the INL component.

FIG. 16 is a diagram for describing an effect produced by the correction in the first embodiment of the present technology. In the drawing, a horizontal axis represents an analog input signal normalized to fall within a range of “0.0” to “1.0”, and a vertical axis represents a digital signal. Furthermore, a rough dotted line is a straight line indicating an ideal input/output relationship, and a fine dotted line indicates a locus of the digital signal Dact before correction corresponding to the input signal. A solid line indicates a locus of the digital signal Dout after the correction corresponding to the input signal.

As illustrated in the drawing, before the correction, a difference between an ideal value and the value of the digital signal Dact might increase, and an INL error occurs. As a result of the correction, however, the value of the digital signal Dout approaches the ideal value, and the INL error can be reduced.

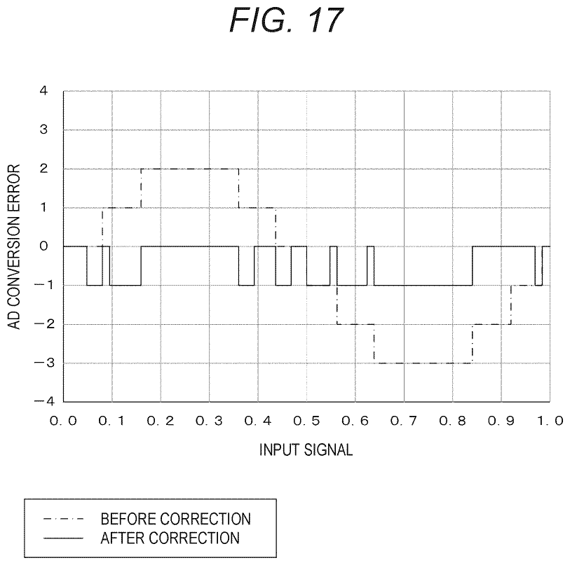

FIG. 17 is a diagram illustrating an example of an AD conversion error corresponding to an input signal according to the first embodiment of the present technology. In the drawing, a horizontal axis represents an analog input signal normalized to fall within a range from “0.0” to “1.0”, and a vertical axis represents the AD conversion error. Furthermore, a dash-dot line indicates the AD conversion error before correction (in other words, Dact-D_{ideal}), and a solid line indicates the AD conversion error after the correction (in other words, Dout-D_{ideal}). As illustrated in the drawing, an error from the ideal value D_{ideal} can be suppressed within 1 LSB (least significant bit) through the correction.

As described above, according to the first embodiment of the present technology, since the correction unit 265 corrects a digital signal using a correction value in the correction value table 261, the circuit scale can be reduced as compared with a case where correction is performed using a nonlinear function.

### 2. Second Embodiment

In the first embodiment described above, the analog-to-digital converter 200 converts an analog signal into an n-bit code (digital signal Dout), but there is a case where improvement in correction accuracy is necessary. An analog-to-digital converter 200 in this second embodiment is different from that according to the first embodiment in that correction accuracy is further improved through sign extension.

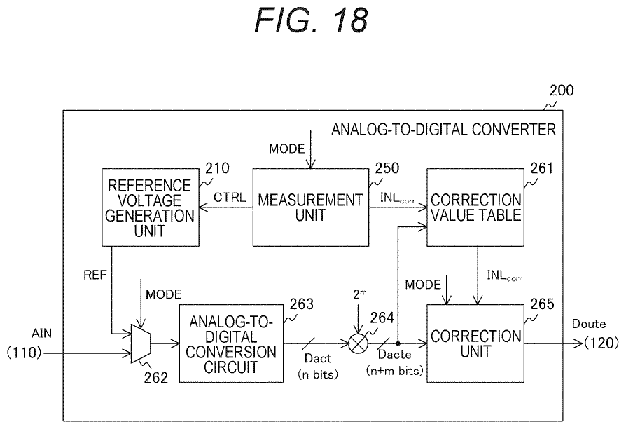

FIG. 18 is a block diagram illustrating a configuration example of the analog-to-digital converter 200 according to the second embodiment of the present technology. The analog-to-digital converter 200 according to the second embodiment is different from that according to the first embodiment in that a multiplier 264 is further included.

The multiplier 264 multiplies the n-bit digital signal Dact by 2^{m} (m is an integer). As a result of the multiplication, bit width of the digital signal is subjected to sign extension from n bits to n+m bits. The extended digital signal is supplied to the correction unit 265 as a digital signal Dacte.

Furthermore, the correction unit 265 according to the second embodiment corrects the digital signal Dacte with a correction value and outputs the corrected digital signal Dacte as Doute.

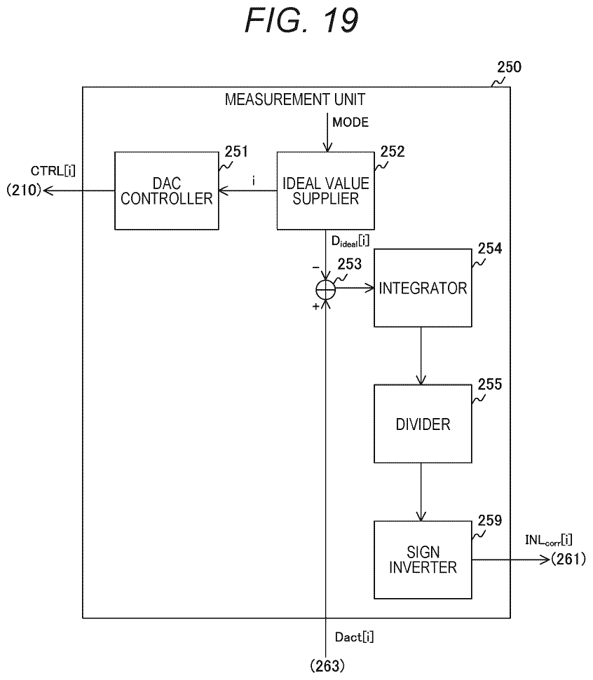

FIG. 19 is a block diagram illustrating a configuration example of a measurement unit 250 according to the second embodiment of the present technology. The measurement unit 250 according to the second embodiment is different from that according to the first embodiment in that an integrator 254 and a divider 255 are further included.

A DAC controller 251 according to the second embodiment controls the reference voltage generation unit 210 to repeatedly generate the corresponding reference voltage Vref[i] for each index i over 2^{m+k} (k is an integer) times.

The adder 253 supplies 2^{m+k} errors Dₑᵣᵣₒᵣ[i] to the integrator 254 for each index i.

The integrator 254 integrates 2^{m+k} errors Dₑᵣᵣₒᵣ[i] for each index i. The integrator 254 supplies a calculation result to the divider 255.

The divider 255 divides the calculation result obtained by the integrator 254 by 2^{k}. The sign inverter 259 holds a value obtained by inverting a sign of a quotient in the correction value table 261 as a correction value INL_{corr}[i].

The correction value INL_{corr}[i] obtained through the above calculation is expressed by the following expression.

### [Math. 1]

$${INL}_{corr} [ i ] = - \frac{{\sum }_{j = 1}^{2 \hat{} ( k + m )} {D}_{error} [ i ]}{{2}^{k}} \qquad Expression 2$$

As a result of the calculation of Expression 2, the measurement unit 250 can generate a correction value for correcting the extended digital signal Dacte.

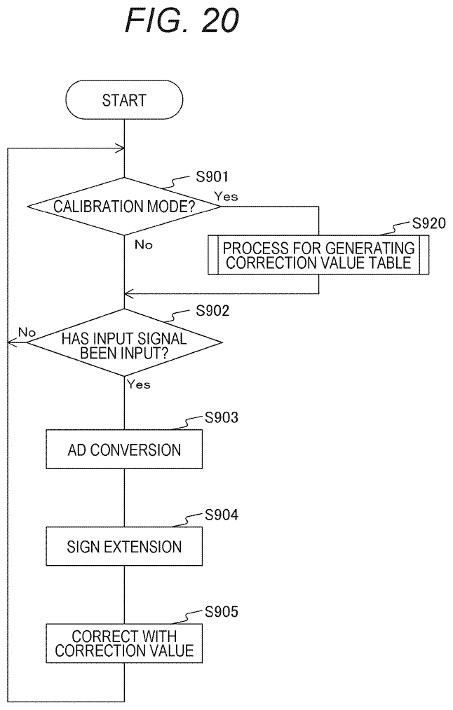

FIG. 20 is a flowchart illustrating an example of operation of the analog-to-digital converter 200 according to the second embodiment of the present technology. The operation of the analog-to-digital converter 200 according to the second embodiment is different from that according to the first embodiment in that step S904 is further performed and step S920 is performed instead of step S910.

After the AD conversion (step S903), the analog-to-digital converter 200 code-extends the digital signal Dact (step S904) and corrects the digital signal Dact with the correction value (step S905).

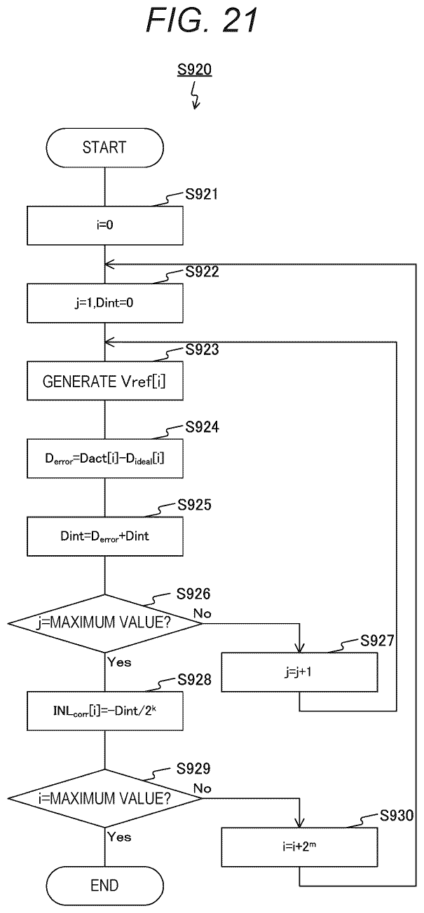

FIG. 21 is a flowchart illustrating an example of a process for generating a correction value table according to the second embodiment of the present technology. The measurement unit 250 sets the index i to an initial value (“0”) (step S921), and sets an index j and a variable Dint to initial values (“1” and “0”) (step S922). The index j indicates the number of integrations. The reference voltage generation unit 210 then generates the reference voltage Vref[i] under the control of the measurement unit 250 (step S923).

After the reference voltage Vref[i] is converted into the digital signal Dact[i], the measurement unit 250 calculates an error Dₑᵣᵣₒᵣ using Expression 1 (step S924).

The measurement unit 250 then updates Dint with a value obtained by adding the error Dₑᵣᵣₒᵣ to Dint (step S925).

The measurement unit 250 determines whether or not the index j is a maximum value (2^{m+k} or the like) (step S926). If the index j is not the maximum value (step S926: No), the analog-to-digital converter 200 increments the index j (step S927), and repeats step S923 and subsequent steps.

If the index j is the maximum value (step S926: Yes), on the other hand, the measurement unit 250 divides Dint by 2^{k} and holds a value obtained by inverting a sign of the quotient in the correction value table 261 as a correction value INL_{corr}[i] (step S928).

The measurement unit 250 then determines whether or not the index i is a maximum value (2^{n+m}−2^{m} or the like) (step S929). If the index i is not the maximum value (step S929: No), the measurement unit 250 adds 2^{m} to the index i (step S930), and repeats step S922 and subsequent steps. If the index i is the maximum value (step S929: Yes), on the other hand, the measurement unit 250 ends the process for generating a correction value table.

Note that the process for generating a correction value table is not limited to the process illustrated in the drawing as long as Expression 2 can be achieved.

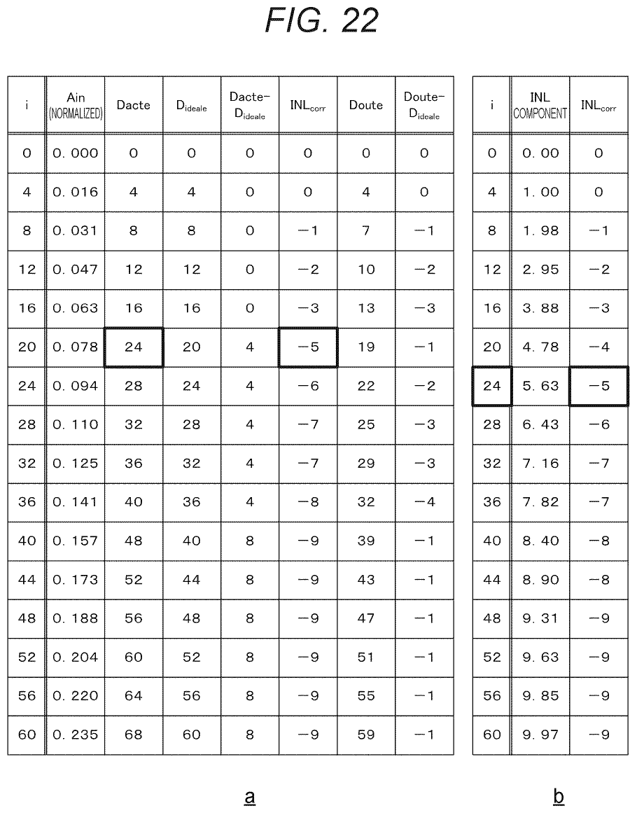

FIG. 22 is a diagram illustrating correction examples and correction values corresponding to indices of 0 to 60 according to the second embodiment of the present technology.

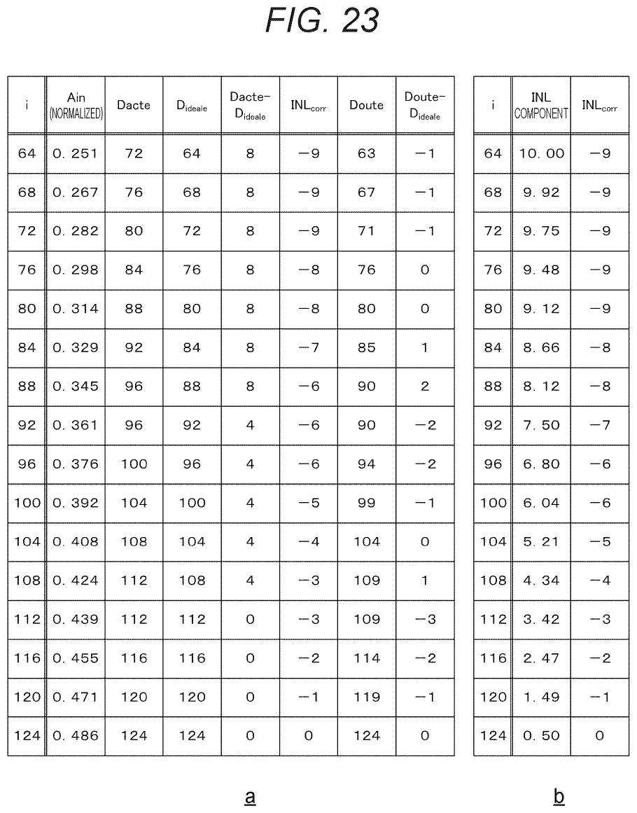

FIG. 23 is a diagram illustrating correction examples and correction values corresponding to indices of 64 to 124 according to the second embodiment of the present technology.

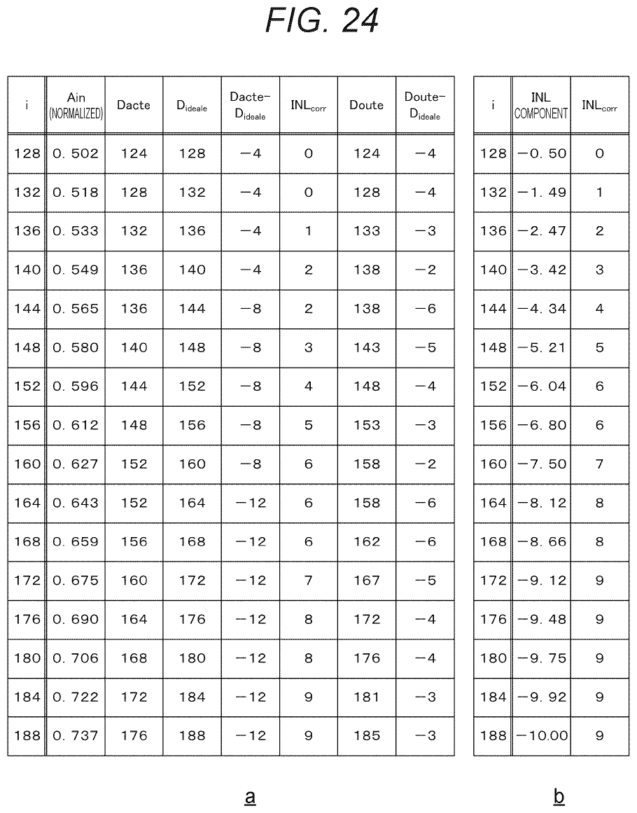

FIG. 24 is a diagram illustrating correction examples and correction values corresponding to indices of 128 to 188 according to the second embodiment of the present technology.

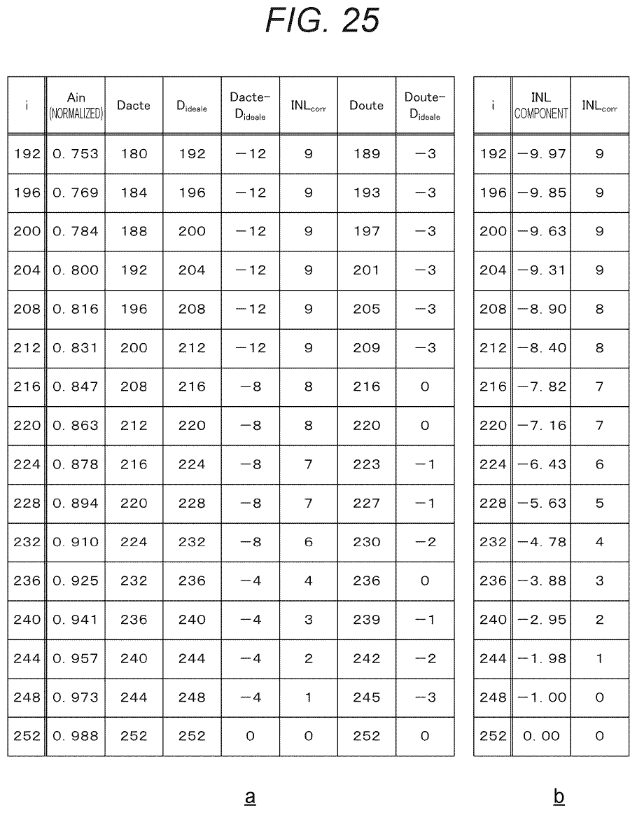

FIG. 25 is a diagram illustrating correction examples and correction values corresponding to indices of 192 to 252 according to the second embodiment of the present technology.

In each of FIGS. 22 to 25, a is a summary of results of the correction, and b in each represents correction values held in the correction value table 261. Bit width of the digital signal before extension is set to 6 bits, and bit width after the extension is set to 8 bits. Furthermore, as the index i, a value extended by multiplying each of 0 to 63 by 2² is used. Furthermore, an ideal value obtained by extending the ideal value D_{ideal} is assumed as D_{ideale}.

A case where AD conversion is performed on the input signal Ain corresponding to the index i of “20” is assumed. In this case, it is assumed that a value of the extended digital signal Dacte is “24”. The correction value INL_{corr} corresponding to the index i having the same value as the digital signal Dacte is “−5” from the correction value table 261. The correction unit 265 adds the correction value to the digital signal Dacte and outputs the obtained “19” as Doute.

Since the ideal value D_{ideale} in a case where the index i is “20” is “20”, an error before the correction (in other words, Dacte-D_{ideale}) is “4”. The error after the correction (in other words, Doute-D_{ideale}), on the other hand, is “−1”, and the INL error is suppressed through the correction.

Note that since the measurement unit 250 generates the correction value from the digital signal Dact before extension using Expressions 1 and 2, the number of correction values is the same as (2⁶ or the like) in the first embodiment as illustrated in FIGS. 22 to 25. As a result, an increase in size of the correction value table 261 can be suppressed.

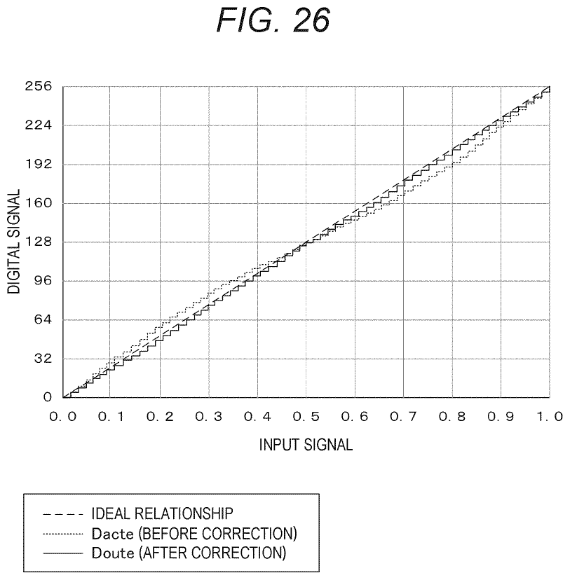

FIG. 26 is a diagram for describing an effect of correction in the second embodiment of the present technology. In the drawing, a horizontal axis represents an analog input signal normalized to fall within a range of “0.0” to “1.0”, and a vertical axis represents a digital signal. Furthermore, a rough dotted line is a straight line indicating an ideal input/output relationship, and a fine dotted line indicates a locus of the digital signal Dacte before correction corresponding to the input signal. A solid line indicates a locus of the digital signal Doute after the correction corresponding to the input signal. As illustrated in the drawing, the correction accuracy is improved by the sign extension, and the INL error can be further reduced.

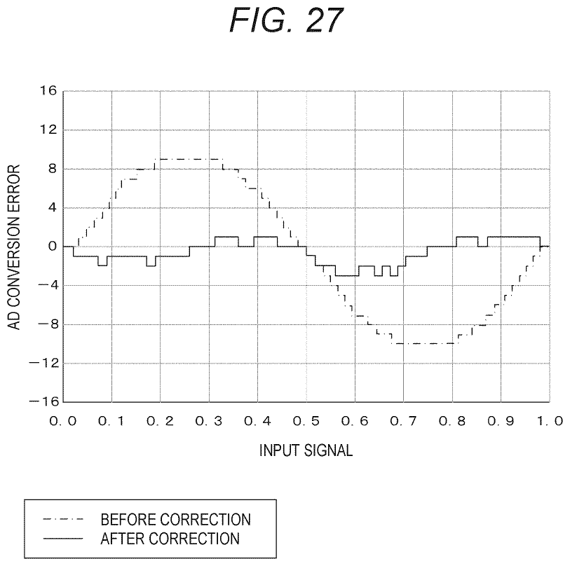

FIG. 27 is a diagram illustrating an example of an AD conversion error corresponding to an input signal according to the second embodiment of the present technology. In the drawing, a horizontal axis represents an analog input signal normalized to fall within a range from “0.0” to “1.0”, and a vertical axis represents the AD conversion error. Furthermore, a dash-dot line indicates the AD conversion error before correction (in other words, Dacte-D_{ideale}), and a solid line indicates the AD conversion error after the correction (in other words, Doute-D_{ideale}). As illustrated in the drawing, the correction accuracy is improved by the sign extension, and the error from the ideal value D_{ideale} can be further suppressed.

As described above, according to the second embodiment of the present technology, since the digital signal is subjected to sign extension, the correction accuracy can be further improved.

### 3. Third Embodiment

In the first embodiment described above, the measurement unit 250 generates the correction value for each value of the digital signal, but in this configuration, the size of the correction value table 261 increases as the resolution increases. An analog-to-digital converter 200 according to a third embodiment is different from that according to the first embodiment in that the size of the correction value table 261 is reduced.

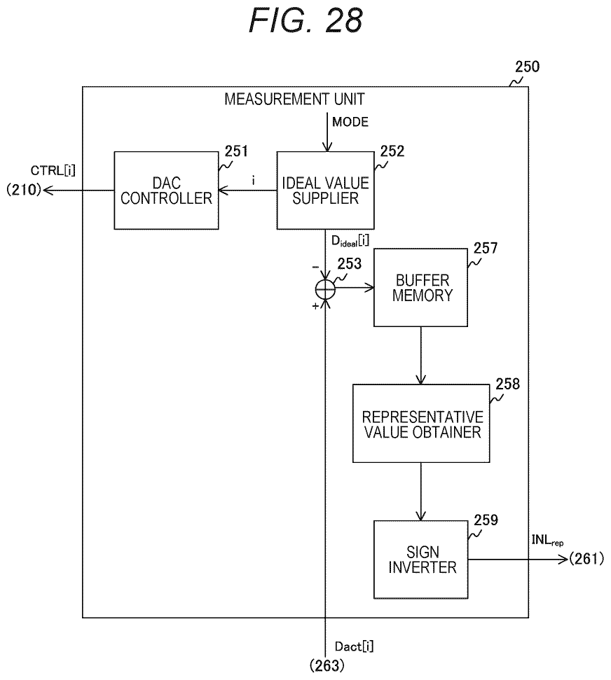

FIG. 28 is a block diagram illustrating a configuration example of a measurement unit 250 according to the third embodiment of the present technology. The measurement unit 250 according to the third embodiment is different from that according to the first embodiment in that a buffer memory 257 and a representative value obtainer 258 are further included.

The adder 253 causes the buffer memory 257 to hold a difference (that is, the error Dₑᵣᵣₒᵣ) between the ideal value D_{ideal} and the digital signal Dact. Here, the value of the digital signal Dact is divided into a plurality of ranges. In a case where the value of the digital signal Dact is 0 to 63, for example, these 64 codes are divided into eight ranges each including eight codes. The buffer memory 257 holds at least eight errors Dₑᵣᵣₒᵣ.

For each range obtained as a result of the division, the representative value obtainer 258 reads the errors Dₑᵣᵣₒᵣ in the range from the buffer memory 257, and obtains a representative value (such as a mode) of the errors Dₑᵣᵣₒᵣ. The sign inverter 259 holds a value obtained by inverting a sign of the representative value for each range in the correction value table 261 as a correction value of the range.

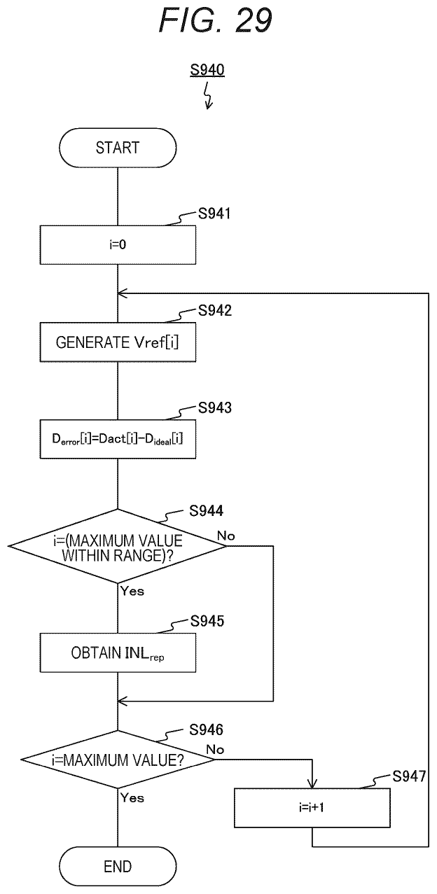

FIG. 29 is a flowchart illustrating an example of a process for generating a correction value table according to the third embodiment of the present technology. The measurement unit 250 sets the index i to an initial value (“0”) (step S941). The reference voltage generation unit 210 then generates the reference voltage Vref[i] (step S942).

In a case where the reference voltage Vref[i] is converted into the digital signal Dact[i], the measurement unit 250 calculates the error Dₑᵣᵣₒᵣ[i] using the following expression and holds the error Dₑᵣᵣₒᵣ[i] in the buffer memory 257 (step S943).

$${D}_{error} [ i ] = Dact [ i ] - {D}_{ideal} [ i ] \qquad Expression 3$$

The measurement unit 250 determines whether or not the index i is a maximum value (7, 15, or the like) within the range obtained as a result of the division (step S944). If i is the maximum value within the range (step S944: Yes), the measurement unit 250 obtains a representative value within the range, and holds a value obtained by inverting a sign of the representative value in the correction value table 261 as a correction value INLᵣₑₚ (step S945).

If i is not the maximum value within the range (step S944: No), or after step S945, the measurement unit 250 determines whether or not the index i is a maximum value (2ⁿ−1 or the like) within all the ranges (step S946).

If the index i is not the maximum value (step S946: No), the measurement unit 250 increments the index i (step S947), and repeats step S942 and subsequent steps. If the index i is the maximum value (step S946: Yes), on the other hand, the measurement unit 250 ends the process for generating a correction value table.

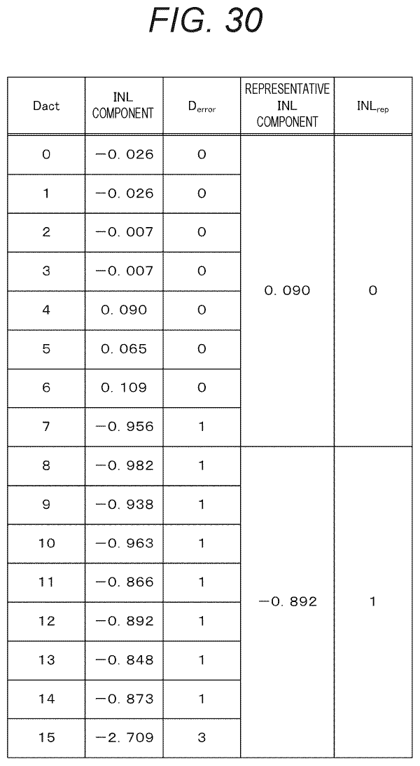

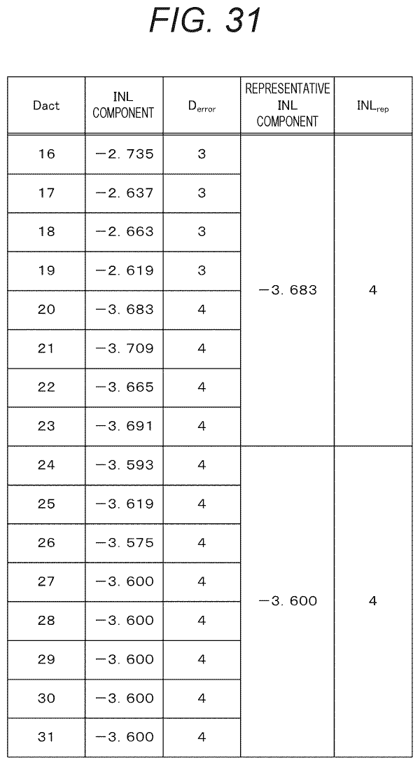

FIG. 30 is a diagram illustrating correction values corresponding to digital signals of 0 to 15 according to the third embodiment of the present technology.

FIG. 31 is a diagram illustrating correction values corresponding to digital signals of 16 to 31 according to the third embodiment of the present technology.

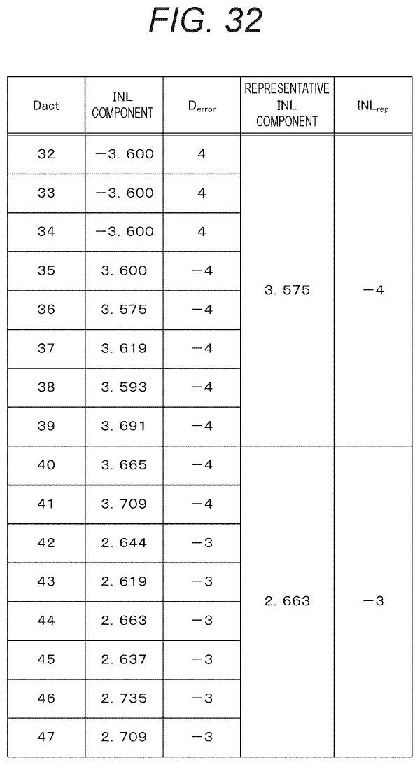

FIG. 32 is a diagram illustrating correction values corresponding to digital signals of 32 to 47 according to the third embodiment of the present technology.

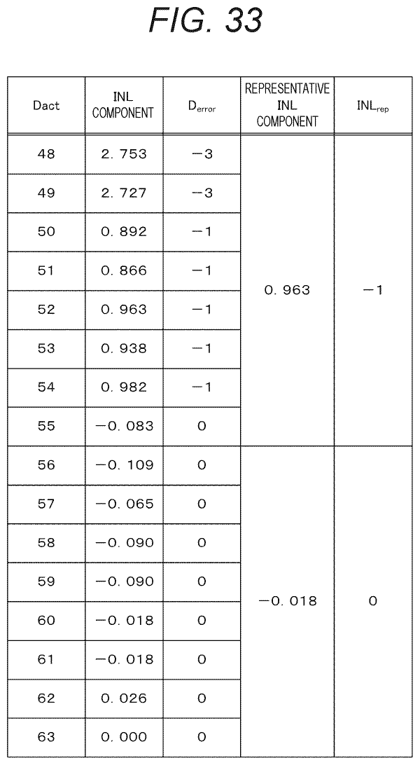

FIG. 33 is a diagram illustrating correction values corresponding to digital signals of 48 to 63 according to the third embodiment of the present technology.

The correction values illustrated in FIGS. 30 to 33 are held in the correction value table 261. In a case where the resolution is 6 bits, the value of the digital signal Dact is 0 to 63, and these are divided into eight ranges. The error Dₑᵣᵣₒᵣ is calculated using Expression 3 for each value of Dact within the ranges. A value obtained by inverting a sign of each of these representative values is held in the correction value table 261 as a correction value INLᵣₑₚ corresponding to the range. For example, a correction value INLᵣₑₚ of “0” is held in association with the range of the digital signal Dact from 0 to 7.

As illustrated in FIGS. 30 to 33, for each range, a value obtained by inverting a sign of a representative value of errors within the range is held in the correction value table 261 as a correction value, so that the size of the correction value table 261 can be reduced.

Note that, in FIGS. 30 to 33, an INL component, a representative INL component within each range, and an error Dₑᵣᵣₒᵣ are described for reference, but these are not held in the correction value table 261.

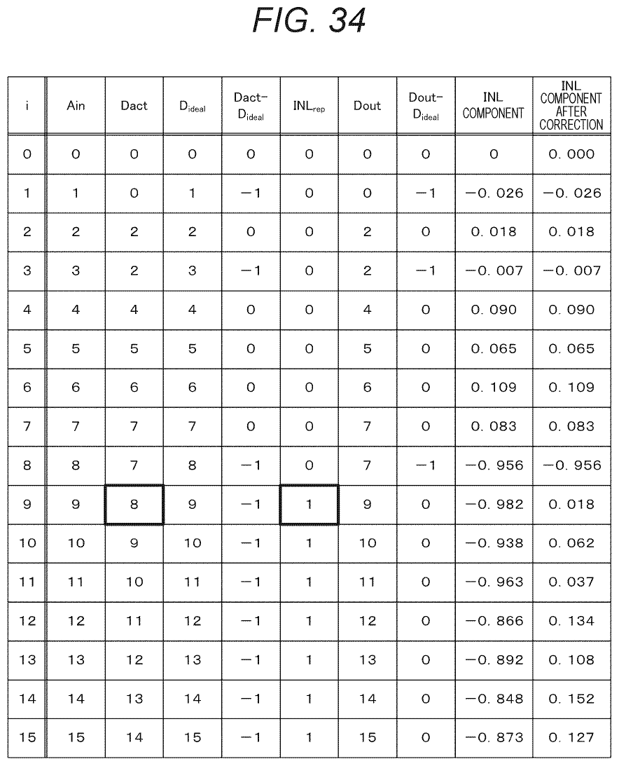

FIG. 34 is a diagram illustrating correction examples corresponding to indices of 0 to 15 according to the third embodiment of the present technology.

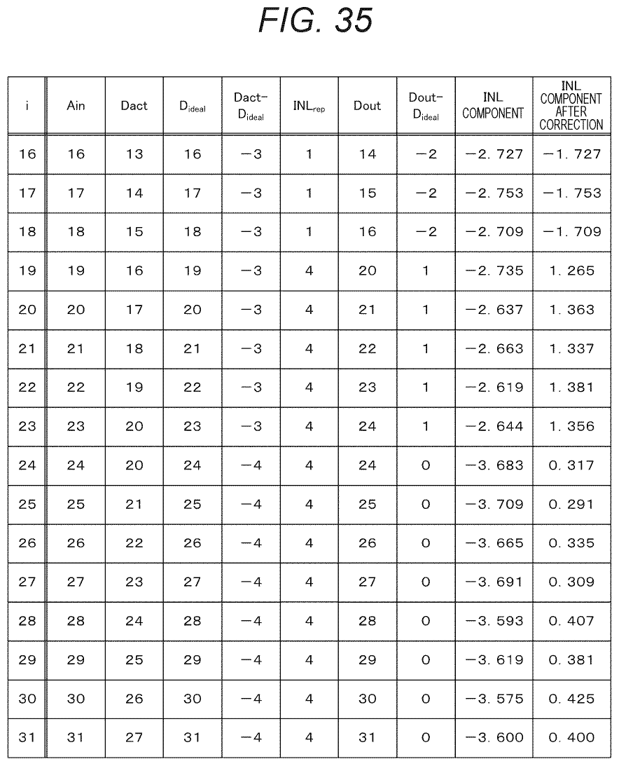

FIG. 35 is a diagram illustrating correction examples corresponding to indices of 16 to 31 according to the third embodiment of the present technology.

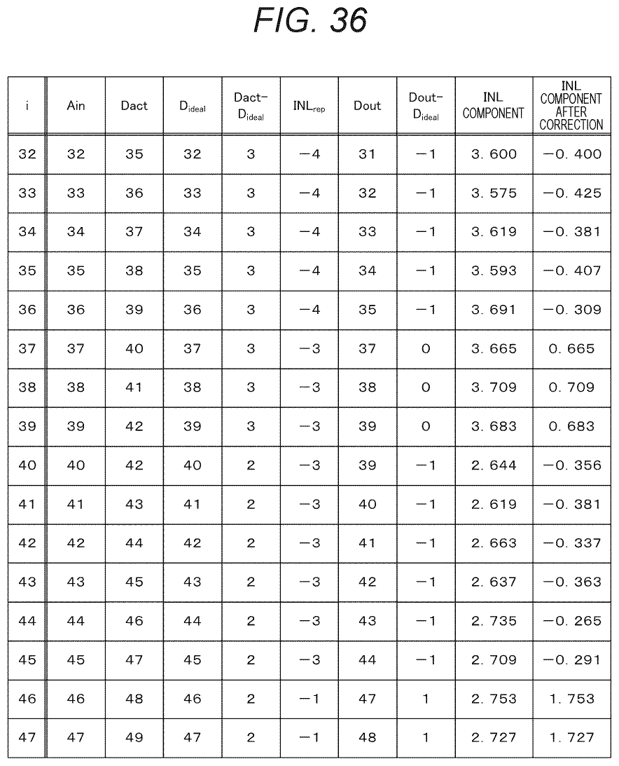

FIG. 36 is a diagram illustrating correction examples corresponding to indices of 32 to 47 according to the third embodiment of the present technology.

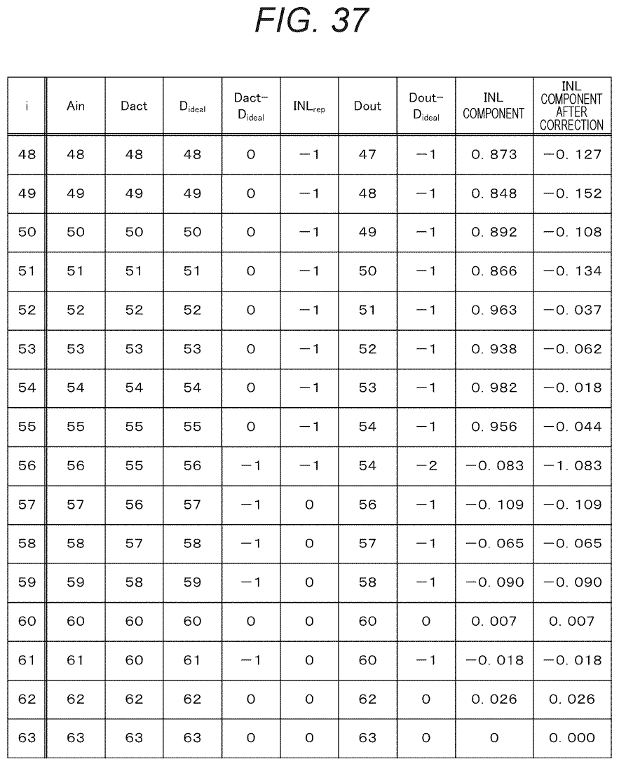

FIG. 37 is a diagram illustrating correction examples corresponding to indices of 48 to 63 according to the third embodiment of the present technology.

A case where AD conversion is performed on the input signal Ain corresponding to the index i of “9” is assumed. In this case, it is assumed that the value of the digital signal Dact is “8”. The correction value INLᵣₑₚ corresponding to the range including the digital signal Dact is “1” from the correction value table 261. The correction unit 265 adds the correction value to the digital signal Dact and outputs the obtained “9” as Dout.

Since the ideal value D_{ideal} in a case where the index i is “9” is “9”, an error before the correction (in other words, Dact-D_{ideal}) is “−1”. The error after the correction (Dout-D_{ideal}), on the other hand, is “0”, and the INL error is suppressed through the correction.

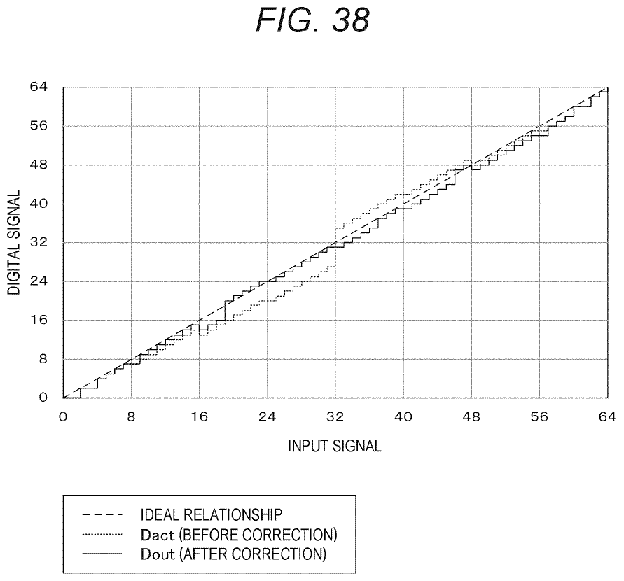

FIG. 38 is a diagram for describing an effect of correction in the third embodiment of the present technology. In the drawing, a horizontal axis represents an input signal, and a vertical axis represents a digital signal. Furthermore, a rough dotted line is a straight line indicating an ideal input/output relationship, and a fine dotted line indicates a locus of the digital signal Dact before correction corresponding to the input signal. A solid line indicates a locus of the digital signal Dout after the correction corresponding to the input signal. As illustrated in the drawing, the INL error can be reduced through the correction.

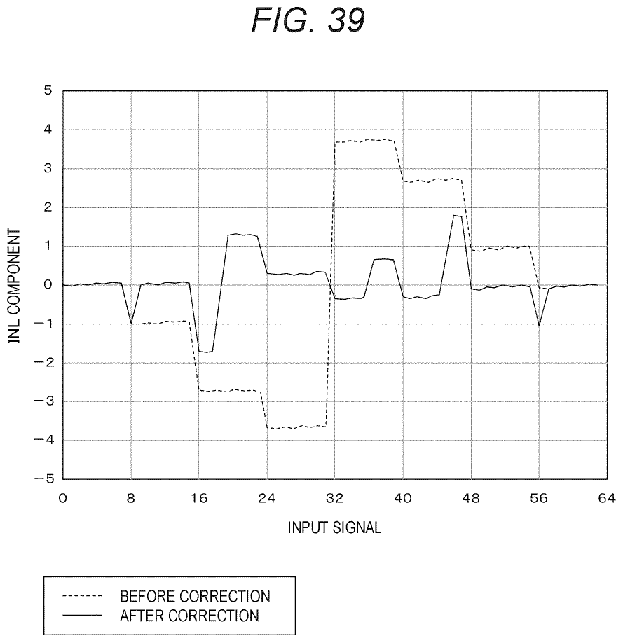

FIG. 39 is a diagram illustrating an example of an INL component before and after the correction according to the third embodiment of the present technology. In the drawing, a vertical axis represents the INL component, and a horizontal axis represents the input signal. Furthermore, a dotted line indicates the INL component before the correction, and a solid line indicates the INL component after the correction. As illustrated in the drawing, the INL component is reduced through the correction.

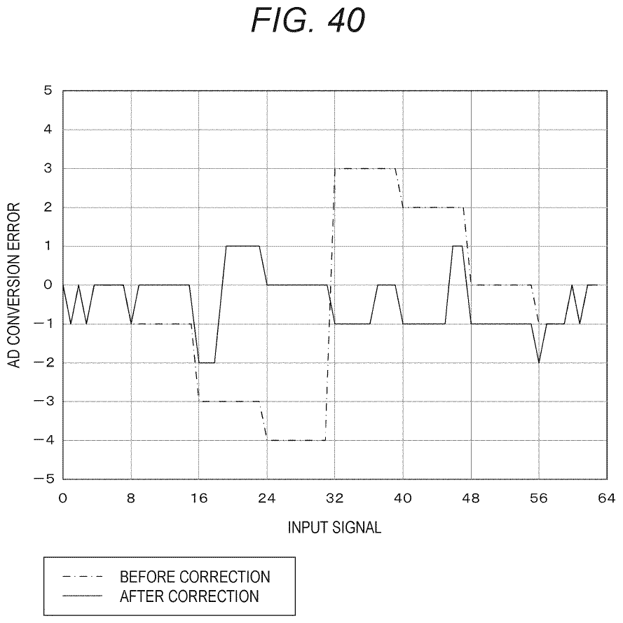

FIG. 40 is a diagram illustrating an example of an AD conversion error corresponding to an input signal according to the third embodiment of the present technology. In the drawing, a horizontal axis represents the input signal, and a vertical axis represents the AD conversion error. Furthermore, a dash-dot line indicates an AD conversion error before correction, and a solid line indicates an AD conversion error after the correction. As illustrated in the drawing, an error from the ideal value D_{ideal} can be suppressed through the correction.

Note that the second embodiment can be applied to the third embodiment.

As described above, according to the third embodiment of the present technology, the correction value table 261 holds a value obtained by inverting a sign of a representative value of errors within each range of a digital signal as a correction value for the range, so that the size of the table can be reduced as compared with the first embodiment.

Note that the embodiments described above show examples for embodying the present technology, and the matters in the embodiments and the matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the scope of the present technology.

Note that advantageous effects described in the present description are merely examples and are not limited, and other advantageous effects may be provided.

Note that the present technology may also have the following configurations.

### (1) an Analog-to-Digital Converter Including:

an analog-to-digital conversion circuit that converts an analog signal into a digital signal;
a correction value table that holds a correction value for correcting a non-linearity error of the analog-to-digital conversion circuit in association with a value of the digital signal; and
a correction unit that corrects the digital signal using the correction value.

### (2) the Analog-to-Digital Converter According to (1), Further Including:

a reference voltage generation unit that generates a predetermined reference voltage;
a selection unit that selects the reference voltage or an input analog signal and supplies the selected reference voltage or input analog signal to the analog-to-digital conversion circuit; and
a measurement unit that obtains the correction value from a measured value of the digital signal corresponding to the reference voltage and a predetermined ideal value.
   (3) The analog-to-digital converter according to (2), in which
an output range of the reference voltage generation unit substantially matches an input range of the analog-to-digital conversion circuit.
   (4) The analog-to-digital converter according to (2) or (3), in which
the measurement unit obtains a difference between the measured value and the ideal value as the correction value, and
the correction value table holds the correction value for each value of the digital signal.
   (5) The analog-to-digital converter according to (2) or (3), in which
values of the digital signal are divided into a predetermined number of ranges,
the measurement unit obtains, for each range, a representative value of differences between measured values and the ideal value within the range as the correction value, and
the correction value table holds the correction value for each range.
   (6) The analog-to-digital converter according to (2) or (3), further including:
a multiplier that performs sign extension on the digital signal through multiplication and that supplies the digital signal to the correction unit, in which
the measurement unit calculates, as the correction value, a value obtained by dividing an integrated value of differences between measured values and the ideal value by a predetermined divisor.
   (7) The analog-to-digital converter according to (6), in which
resolution of the analog-to-digital conversion circuit is n bits, where n is an integer, the multiplier multiplies the digital signal by 2^{m}, where m is an integer,
the number of integrations of the differences is 2^{(k+m)}, where k is an integer, and
the divisor is 2^{k}
   (8) An electronic device including:
an analog-to-digital conversion circuit that converts an analog signal into a digital signal;
a correction value table that holds a correction value for correcting a non-linearity error of the analog-to-digital conversion circuit in association with a value of the digital signal;
a correction unit that corrects the digital signal using the correction value; and
a signal processing unit that performs predetermined processing on the corrected digital signal.
   (9) A method for controlling an analog-to-digital converter, the method including:
an analog-to-digital conversion step of converting an analog signal into a digital signal; and
a correction step of correcting the digital signal using a correction value for correcting a non-linearity error of the analog-to-digital conversion circuit obtained from a correction value table that holds the correction value in association with a value of the digital signal.

### REFERENCE SIGNS LIST

100 Reception device
110 Antenna
120 Tuner
130 Demodulation unit
131 Demodulator
140 Video/audio processing unit
141 Demultiplexer
142 Decoder
150 Display
200 Analog-to-digital converter
210 Reference voltage generation unit
211 Thermometer code DAC
212 R-2R ladder DAC
213 Current source
214 Switch
215 Resistance element
250 Measurement unit
251 DAC controller
252 Ideal value supplier
253 Adder
254 Integrator
255 Divider
257 Buffer memory
258 Representative value obtainer
259 Sign inverter
261 Correction value table
262 Multiplexer
263 Analog-to-digital conversion circuit
264 Multiplier
265 Correction unit

What is claimed is:

1. An analog-to-digital converter, comprising:
an analog-to-digital conversion circuit that converts an analog signal into a digital signal;
a correction value table that holds a correction value for correcting a non-linearity error of the analog-to-digital conversion circuit in association with a value of the digital signal; and
a correction unit that corrects the digital signal using the correction value.

2. The analog-to-digital converter according to claim 1, further comprising:
a reference voltage generation unit that generates a predetermined reference voltage;
a selection unit that selects the reference voltage or an input analog signal and supplies the selected reference voltage or input analog signal to the analog-to-digital conversion circuit; and
a measurement unit that obtains the correction value from a measured value of the digital signal corresponding to the reference voltage and a predetermined ideal value.

3. The analog-to-digital converter according to claim 2, wherein
an output range of the reference voltage generation unit substantially matches an input range of the analog-to-digital conversion circuit.

4. The analog-to-digital converter according to claim 2, wherein
the measurement unit obtains a difference between the measured value and the ideal value as the correction value, and
the correction value table holds the correction value for each value of the digital signal.

5. The analog-to-digital converter according to claim 2, wherein
values of the digital signal are divided into a predetermined number of ranges,
the measurement unit obtains, for each range, a representative value of differences between measured values and the ideal value within the range as the correction value, and
the correction value table holds the correction value for each range.

6. The analog-to-digital converter according to claim 2, further comprising:
a multiplier that performs sign extension on the digital signal through multiplication and that supplies the digital signal to the correction unit, wherein
the measurement unit calculates, as the correction value, a value obtained by dividing an integrated value of differences between measured values and the ideal value by a predetermined divisor.

7. The analog-to-digital converter according to claim 6, wherein
resolution of the analog-to-digital conversion circuit is n bits, where n is an integer,
the multiplier multiplies the digital signal by 2^{m}, where m is an integer,
the number of integrations of the differences is 2^{(k+m)}, where k is an integer, and
the divisor is 2^{k}.

8. An electronic device comprising:
an analog-to-digital conversion circuit that converts an analog signal into a digital signal;
a correction value table that holds a correction value for correcting a non-linearity error of the analog-to-digital conversion circuit in association with a value of the digital signal;
a correction unit that corrects the digital signal using the correction value; and
a signal processing unit that performs predetermined processing on the corrected digital signal.

9. A method for controlling an analog-to-digital converter, the method comprising:
an analog-to-digital conversion step of converting an analog signal into a digital signal; and
a correction step of correcting the digital signal using a correction value for correcting a non-linearity error of the analog-to-digital conversion circuit obtained from a correction value table that holds the correction value in association with a value of the digital signal.
